(19) United States
(12) Patent Application Publication
(10) Pub. No.: US 2015/0050420 A1
(43) Pub. Date: Feb. 19, 2015

(54) METHOD FOR MANUFACTURING METAL FILM

(71) Applicant: AISIN SEIKI KABUSHIKI KAISHA, Kariya-shi (JP)

(72) Inventors: Takashi HARA, Obu-shi (JP); Hirofumi KOIKE, Anjo-shi (JP); Kazuki MIZUTANI, Miyoshi-shi (JP)

(73) Assignee: AISIN SEIKI KABUSHIKI KAISHA, Kariya-shi (JP)

(21) Appl. No.: 14/334,864

(22) Filed: Jul. 18, 2014

(30) Foreign Application Priority Data
Aug. 19, 2013 (JP) 2013-169788

(51) Int. Cl. C23C 14/14; C23C 14/58; C23C 14/34

(52) U.S. Cl. CPC C23C 14/14; C23C 14/34; C23C 14/5806
USPC 427/250; 204/192.12

(57) ABSTRACT

A method for manufacturing a metal film being formed on a surface of a non-electric conductive base material includes processes of a deposition process of releasing a metal being formed in a particle or being vaporized from at least one of targets, the target being made of solid metal and depositing a metal thin film on the surface of the base material by having the released metal hit the surface of the base material from a plurality of directions; and a crack forming process of forming a crack in the metal thin film by applying thermal stress to the metal thin film.

### CROSS REFERENCE TO RELATED APPLICATIONS

This application is based on and claims priority under 35 U.S.C. §119 to Japanese Patent Application 2013-169788, filed on Aug. 19, 2013, the entire content of which is incorporated herein by reference.

### TECHNICAL FIELD

This disclosure generally relates to a method for manufacturing a metal film.

### BACKGROUND DISCUSSION

A door handle for a smart entry system assembled on a vehicle includes a door handle body and an antenna. The door handle body is made from a non-electric conductive resin base material. The antenna is mounted to the door handle body and receives signals which are sent from a smart key. A film (hereinafter referred to as a metal film) having metallic luster is formed to an outer surface of the door handle body (base material) to improve designability of the door handle.

The door handle for the smart entry system is required to receive the signals which are sent from the smart key precisely. In addition, the door handle for the smart entry system is required to precisely detect a change in capacitance caused by a touch of a human body to a predetermined position of the door handle for the smart entry system in order to open and close a door of the vehicle when an occupant touches the predetermined position. The metal film formed on the outer surface of the door handle for the smart entry system is required to include high radio wave permeability in order to receive the radio wave which is sent from the smart key precisely. Along with that, the metal film formed on the outer surface of the door handle for the smart entry system is required to include high electrical insulation properties in order to prevent an incorrect operation when the occupant touches a position other than the predetermined position of the door handle for the smart entry system.

A known metal film is disclosed in JP2011-163903A (hereinafter referred to as Patent reference 1). The metal film disclosed in Patent reference 1 is configured to include radio wave permeability by forming cracks in the film by baking treatment (or after baking treatment) after forming an electroless nickel plating film on a surface of a base material.

Another known metal film is disclosed in JP2009-286082A (hereinafter referred to as Patent reference 2). The metal film disclosed in Patent reference 2 is configured to include radio wave permeability and electrical insulation properties by forming cracks in the film. The cracks are formed by a volume expansion of a heated poly-carbonate after forming an aluminum film and chrome film on a surface of a non-electric conductive polycarbonate resin base material by sputtering.

Because the metal film disclosed in Patent reference 1 corresponds to the electroless nickel plating film, the film is required to have many steps, for example, catalyzer process, accelerator process, activator process, and electroless nickel process to be formed, leading to inferior productivity. In addition, because the film is required to be washed between the processes, a facility for effluent treatment is required, leading to high facility cost.

According to Patent references 1 and 2, the cracks are formed in the film based on a difference in thermal expansion of the base material and thermal expansion of the film by heating. Because the cracks are formed as outcomes of the expansion, the orientation of the cracks cannot be controlled. Accordingly, the cracks may be observed as undesired lines and may impair the designability of the exterior appearance of the door handle.

A need thus exists for a method for manufacturing a metal film which is not susceptible to the drawback mentioned above.

### SUMMARY

According to an aspect of this disclosure, a method for manufacturing a metal film being formed on a surface of a non-electric conductive base material includes processes of a deposition process of releasing a metal being formed in a particle or being vaporized from at least one of targets, the target being made of solid metal and depositing a metal thin film on the surface of the base material by having the released metal hit the surface of the base material from a plurality of directions; and a crack forming process of forming a crack in the metal thin film by applying thermal stress to the metal thin film.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a schematic view of a sputtering device which is one example of deposition devices according to an embodiment disclosed here;

FIG. 2A is a schematic side view illustrating a state where metal particles released from a target travel in a specific direction toward a base material according to the embodiment;

FIG. 2B is a schematic side view illustrating a state where the metal particles are deposited on a surface of the base material according to the embodiment;

FIG. 2C is a schematic top view illustrating a state where the metal particles are deposited on the surface of the base material according to the embodiment;

FIG. 3 is a schematic view of a metal thin film which is formed with lined cracks;

FIG. 4 is a view illustrating a state where the metal particles hit the base material from plural directions to be deposited on the surface of the base material;

FIG. 5 is a plan view illustrating changes in a positional relationship between the target and the base material in a case where the base material rotates relative to the target;

FIG. 6 is a plan view illustrating the positional relationship between the plural targets and the base material in a case where the plural targets are placed at different positions;

FIG. 7 is a view illustrating a state where the metal particles sputtered from the plural targets hit the base material;

FIG. 8 is a view illustrating each positional relationship between each of test panels which are mounted on a table and the target according to a second comparison example;

FIG. 9 is microphotographs of the metal films which are formed on surfaces of the test panels, the microphotographs placed in the same order of the positions of the test panels on the table according to the second comparison example;

FIG. 10A is a microphotograph of the metal film which is formed using a method described in a first practical example;

FIG. 10B is a microphotograph of the metal film which is formed using a method described in a second practical example;

FIG. 10C is a microphotograph of the metal film which is formed using a method described in a third practical example;

FIG. 10D is a microphotograph of the metal film which is formed using a method described in a fourth practical example;

FIG. 10E is a microphotograph of the metal film which is formed using a method described in a fifth practical example;

FIG. 10F is a microphotograph of the metal film which is formed using a method described in a sixth practical example;

FIG. 10G is a microphotograph of the metal film which is formed using a method described in a seventh practical example; and

FIG. 10H is a microphotograph of the metal film which is formed using a method described in a first comparison example.

### DETAILED DESCRIPTION

According to an embodiment, a metal film is formed via a deposition process and a crack forming process. In the deposition process, metal being formed in particles or being vaporized is released from a target which is made of solid metal and is used for metal film deposition by being hit by argon ion (Ar+). The released metal hits a surface of a non-electric conductive base material from plural directions to deposit a metal thin film on the surface of the base material. In the crack forming process, thermal stress is applied to the metal thin film which is formed on the surface of the base material to form cracks in the metal thin film.

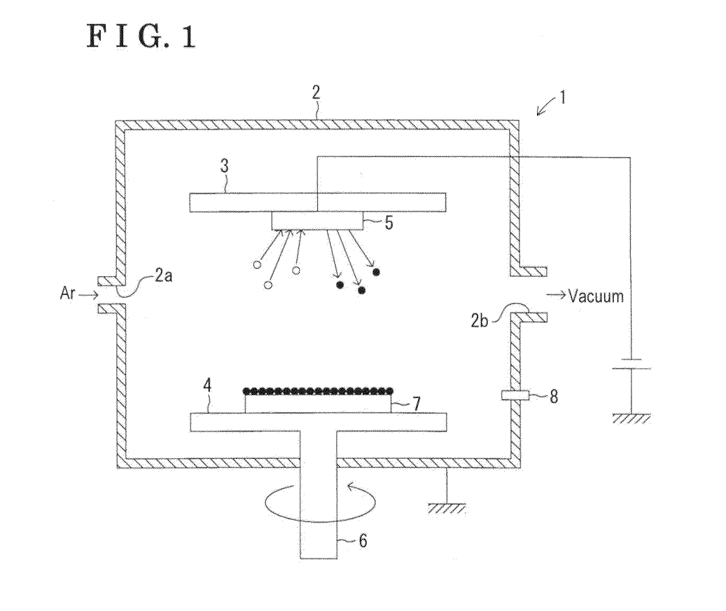

A deposition device is used to deposit the metal thin film on the surface of the base material in the deposition process. As shown in FIG. 1, a sputtering device 1 according to the embodiment is provided with a casing 2, a holding plate 3 and a disc-shaped table 4. The casing 2 includes a space inside thereof. The holding plate 3 and the table 4 are positioned to face with each other in an up-down direction within the casing 2 in FIG. 1. A target 5 made of solid metal is held at a lower surface of the holding plate 3 in FIG. 1.

The disc-shaped table 4 is connected to a rotation shaft 6 which is positioned at a center portion of the table 4 and extends downward from a center portion of the table 4. The table 4 is rotatably configured with the rotation shaft 6 which serves as a pivot center. A base material 7 is mounted on an upper surface of the table 4 in FIG. 1. The base material 7 being mounted on the table 4 rotates in response to the rotation of the table 4. According to the embodiment, the base material 7 corresponds to a door handle body which is configured with a contour of an outside door handle of a vehicle. The base material 7 is made of non-electric conductive (insulative) resin, for example, synthetic resin of poly-carbonate resin, or PC resin and polybutylene terephthalate resin, or PBT resin. Further, the surface of the base material 7 is formed with a smooth layer which is made of, for example, acryl resin with a thickness of 20 μm by ultraviolet hardening. The surface of the base material 7 is smooth because of the smooth layer.

As shown in FIG. 1, the casing 2 is provided with an inert gas inlet 2a and an air exhaust opening 2b. The inert gas inlet 2a introduces argon gas which is inert gas to an inside of the casing 2. The air exhaust opening 2b exhausts air inside the casing 2. A pressure sensor 8 is mounted to the casing 2 to detect gas pressure level inside the casing 2.

The metal thin film is formed on the surface of the base member 7 by using the sputtering device 1. First, the casing 2 is decompressed and argon gas is introduced to the casing 2 so that a pressure level (i.e., deposition pressure level) within the casing 2 reaches a predetermined pressure level. Then, a glow discharge is generated between the table 4 and the target 5 so that argon gas within the casing 2 is plasmatized. Accordingly, argon ion (Ar+) is generated. The generated argon ion hits the cathodic target 5 so that metal particles are sputtered, or released from the target 5. As shown in FIG. 1, argon ion is illustrated as white circles, whereas the metal particles sputtered from the target 5 are illustrated as black circles. Because the target 5 is held by the holding plate 3 which faces the table 4, the metal particles sputtered from the target 5 hit the surface of the base material 7 which is mounted on the table 4. The metal particles hit the surface of the base material 7 and are deposited on the surface of the base material 7. Thus, the metal thin film is deposited on the surface of the base material 7 (an upper surface of the smooth layer) in the deposition process. When the thickness of the metal thin film reaches a predetermined thickness, the glow discharge is stopped to terminate the deposition process. The aforementioned sputtering method corresponds to a glow discharge sputtering method using diode direct current, or diode DC. Alternatively, in addition to the aforementioned sputtering method, the metal thin film may be deposited by using a high-frequency sputtering method and a magnetron sputtering method.

After the deposition process, the cracks are formed in the metal thin film in the crack forming process. In the crack forming process, thermal stress is applied to the metal thin film, for example, by heating the base material 7 on which the metal thin film is formed. In this case, the base material 7 on which the metal thin film is formed is held in a thermostatic oven and is held in the thermostatic oven at a predetermined temperature and at a predetermined time. Accordingly, thermal stress is generated by a difference between a coefficient of linear thermal expansion of the metal thin film and a coefficient of linear thermal expansion of resin of which the base material 7 is made. Then, thermal stress may be applied to the metal thin film. By applying thermal stress to the metal thin film, the metal thin film is torn to form the cracks.

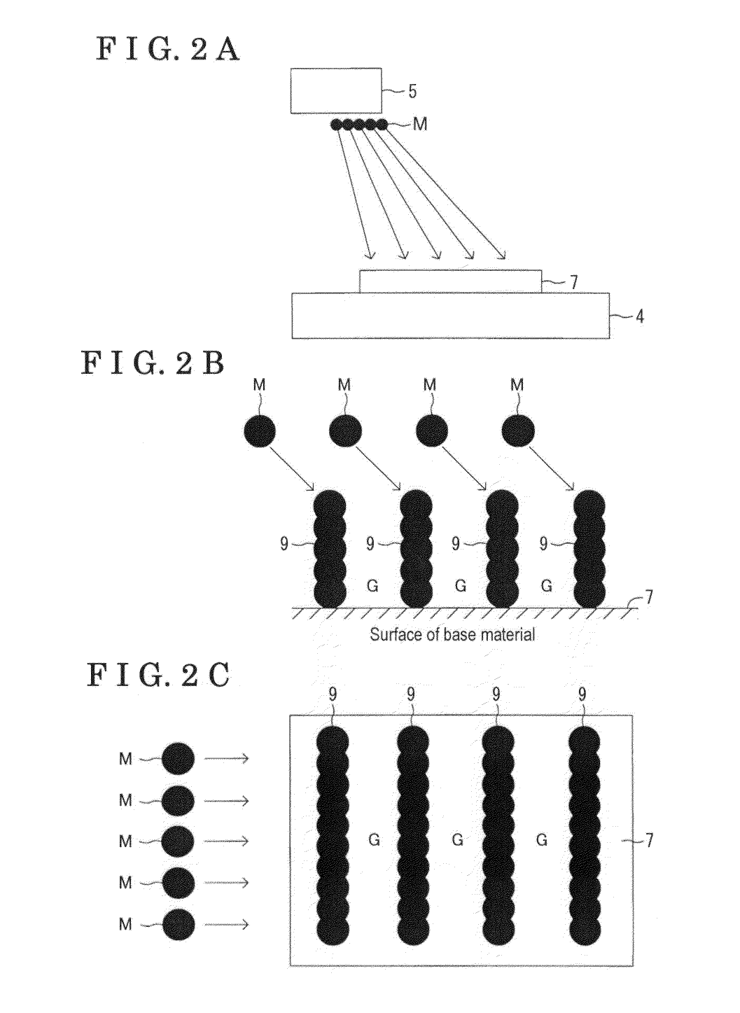

The metal particles are sputtered from the target 5 in the deposition process and travel in a specific direction. FIG. 2A, FIG. 2B and FIG. 2C show views illustrating the metal particles travelled from the target 5 travel in a specific direction, hit the base material 7, and are deposited on the surface of the base material 7. As shown in FIG. 2B, when the metal particles M are travelled from a direction oblique to the surface of the base material 7, the metal particles M are deposited on the surface of the base material 7 to form, or grow a wall-shaped metal layer 9. In addition, gap portions G are formed on the surface of the base material 7 because the metal particles M are blocked by the wall-shaped metal layers 9 and are not travelled to be deposited on the surface of the base material 7. The metal particles M are not deposited, or if any, are less deposited on the gaps G. As shown in FIG. 2C illustrating the gap G from a top view, the gap G is formed in a long, narrow way on the surface of the base material 7 along a direction orthogonal to a travelling direction (in an arrowed direction) of the metal particles M to the base material 7.

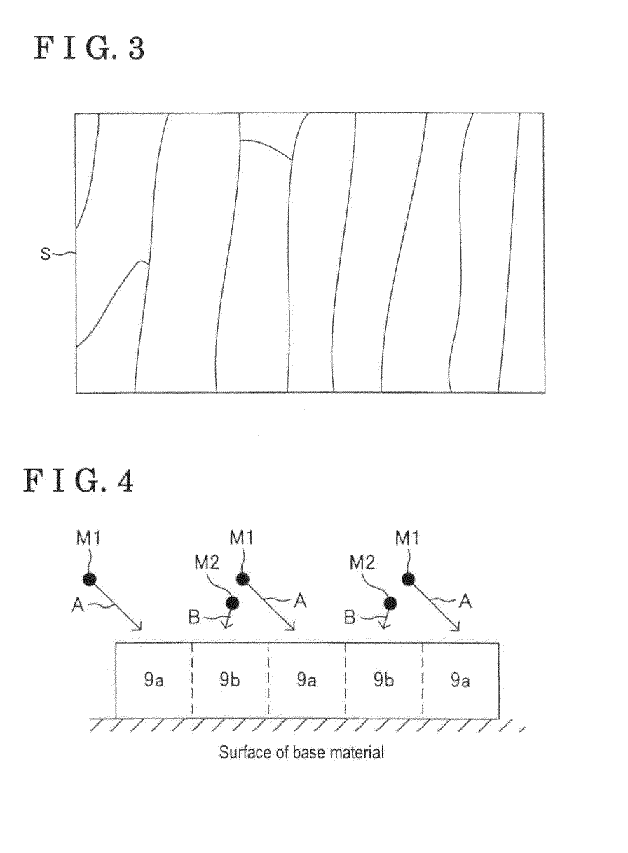

When the long and narrow gap G is formed on the surface of the base material 7, the metal thin film is formed to include different tensile strengths depending on stretching directions. In particular, because the metal layers 9 are connected to each other and extend in a longitudinal direction of the gap G, the metal thin film includes high tensile strength in the longitudinal direction of the gap G. On the other hand, because the metal layers 9 are not connected to each other in a direction orthogonal to the longitudinal direction of the gap G, the base material 7 includes low tensile strength in the direction orthogonal to the longitudinal direction of the gap G. In a case where the metal thin film includes the different tensile strengths, the metal thin film is cracked to be divided in a direction of low tensile strength, that is, the metal thin film is cracked at a position including low tensile strength when applying thermal stress to the metal thin film in the crack forming process after the deposition process. As a result, as shown in FIG. 3, a line-like crack (lined crack) is formed to extend along a specific direction in the metal thin film S. As shown in FIG. 3, in a case where the lined crack is formed, the exterior appearance of the door handle is impaired, leading to inferior designability. Further, because the lined crack is formed, the metal film is divided fewer in the extending direction of the lined cracks. Thus, the electrical insulation properties are deteriorated in the extending direction of the lined cracks, that is, the electrical insulation properties are deteriorated at the cracked position. Accordingly, the properties regarding electrical insulation, for example, radio wave permeability and electrical insulation properties are adversely influenced.

That is, in a case where the metal particles M hit the surface of the base material 7 from a specific direction in the deposition process, the lined crack is formed on the surface of the base material 7. Accordingly, the surface of the base material 7 cannot be coated with the metal film which satisfies requirements for the exterior appearance of the door handle and for the functionality of the door handle body. This indicates that the quality of the metal film is enhanced by having the metal particles M hit the surface of the base material 7 from the plural directions in the deposition process.

As shown in FIG. 4, a metal layer 9a is formed by depositing a metal particle M1 which is travelled from a direction of an arrow A. A metal layer 9b is formed by depositing a metal particle M2 which is travelled from a direction of an arrow B, the direction which is different from the direction of the arrow A. The metal particle M2 is travelled from the direction of the arrow B which is opposite to the travelling direction of the arrow A of the metal particle M1, or which intersects the travelling direction of the arrow A of the metal particle M1 from the opposite direction relative to a perpendicular line relative to the surface of the base material 7 when seeing from a direction parallel to the surface of the base material 7. The metal layer 9b is formed to cover a gap between the plural metal layers 9a, 9a by being interposed therebetween. Accordingly, the metal particles M1, M2 are deposited on the entire surface of the base material 7, and the metal thin film is formed to include the tensile strengths which are substantially similar in any direction. That is, the metal thin film includes the isotropic tensile strengths. Thus, when thermal stress is applied to the metal thin film in the crack forming process after the deposition process, the metal thin film is cracked to form similar size of cracks, or to form net-shaped cracks, or substantially net-shaped cracks, or island-shaped cracks without having orientation. Because the lined cracks extending in a specific direction are not formed, the surface of the base material 7 may be provided with the metal film which has favorable designability of the exterior appearance of the door handle, while including high electrical insulation properties and high radio wave permeability.

Various methods may be adopted to have the metal particles M hit the surface of the base material 7 from the plural directions in the deposition process. For example, the base material 7 rotates relative to the target 5 during the deposition process. By rotating the base material 7, the orientation, or the posture of the base material 7 relative to a travelling direction of the metal particles M which are sputtered from the target 5 changes continuously. Accordingly, the metal particles M hit the base material 7 from different directions continuously. Thus, the metal particles M hit the surface of the base material 7 from the plural directions.

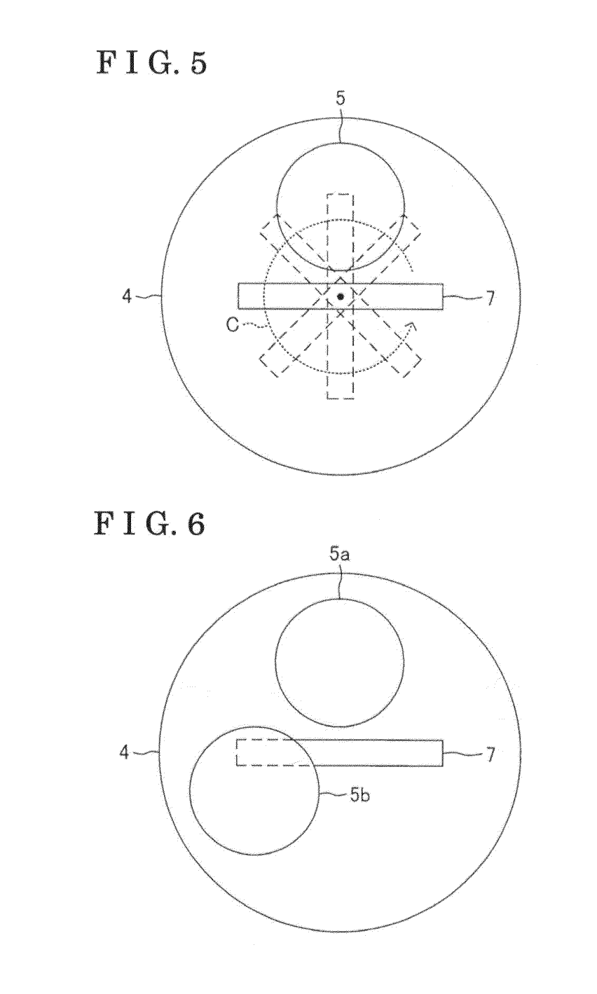

In this case, as described above, the table 4 of the sputtering device 1 shown in FIG. 1 is rotatable about the rotation shaft 6 which serves as the pivot center. Thus, the base material 7 which is mounted on the table 4 rotates relative to the target 5 by rotating the table 4. As shown in FIG. 5, the elongated base material 7 (i.e., the door handle body of the outside door handle) is mounted on a center of the table 4. Seeing from a direction of the rotational axis of the table 4 and the base material 7, the target 5 is placed relative to the table 4 so as to have a center at a position away from a center of the table 4. When the table 4 rotates, the base material 7 rotates in a direction of an arrow C relative to the target 5 in FIG. 5. The pivot center of the base material 7 is positioned at a position different from a center position of the target 5. Because the base material 7 rotates relative to the target 5, the orientation, or the posture of the base material 7 relative to the target 5 changes. In other words, the base material 7 is rotatably configured relative to the target 5 to change the orientation, or the posture of the base material 7 continuously relative to the travelling direction of the metal particles M which are sputtered from the target 5. Accordingly, the metal particles M hit the surface of the base material 7 from the plural directions in the deposition process.

Alternatively, the plural targets may be placed at different positions to release the metal particles M from each of the plural targets in order to have the metal particles M hit the surface of the base material 7 from the plural directions in the deposition process. As shown in FIG. 6, two targets 5a, 5b are placed at the different positions when seeing from a direction orthogonal to the upper surface of the base material 7, that is, the surface on which the metal thin film is formed.

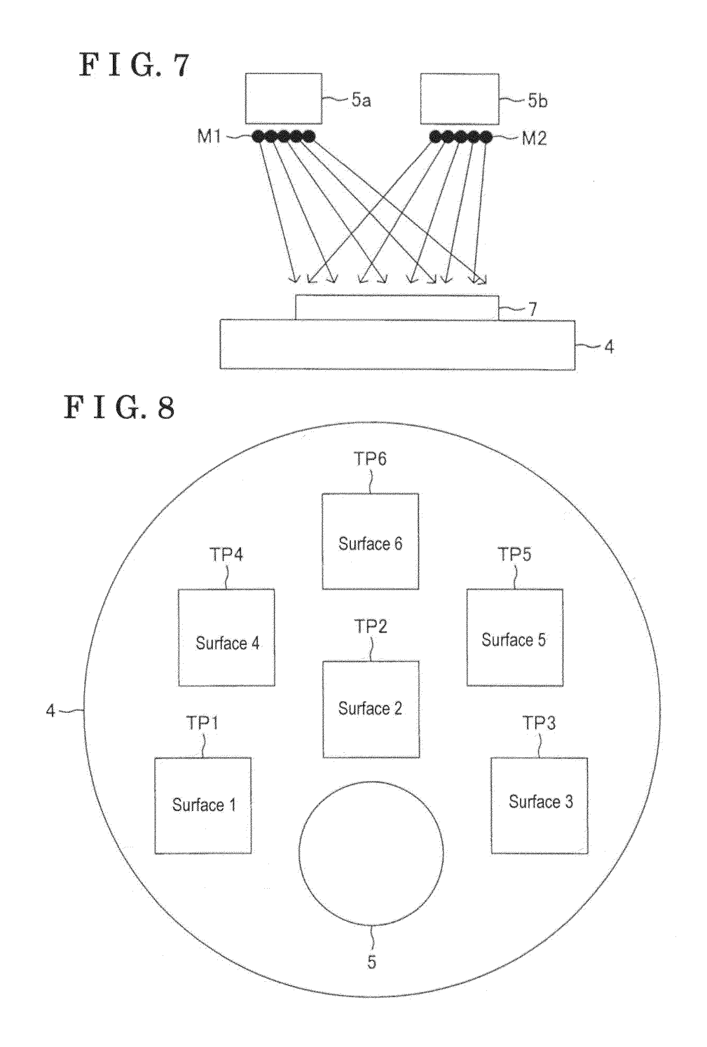

As shown in FIG. 7, the metal particle M1 sputtered from the target 5a travels from a direction which is different from a travelling direction of the metal particle M2 sputtered from the target 5b to be deposited on the surface of the base material 7. Especially, seeing from a direction parallel to the surface of the base material 7 in FIG. 7, the metal particle M1 travels from the direction which is opposite to the travelling direction of the metal particle M2, or which intersects the travelling direction of the metal particle M2 from the opposite direction to be deposited on the surface of the base material 7 relative to the perpendicular line relative to the surface of the base material 7. Accordingly, the metal particles M1, M2 hit the surface of the base material 7 from the plural directions in the deposition process.

The deposition pressure level (i.e., atmospheric gas pressure level within the casing 2) may be equal to or higher than 0.7 Pascals, or 0.7 Pa in the deposition process in order to have the metal particles hit the surface of the base material 7 from the plural directions. The amount of gas within the casing 2 becomes greater as the deposition pressure level increases. Thus, the frequency of the hitting of the metal particles sputtered from the target 5 to gas molecules (for example, argon molecules) which are in the casing 2 increases. When the metal particles sputtered from the target 5 hit the molecules which are in the atmosphere, the travelling direction of the metal particles changes by the collision with the molecules. In particular, when the deposition pressure level is equal to or higher than 0.7 Pa, the metal particles sputtered from the target 5 hit the molecules which are in the casing 2 repeatedly, and lose orientation in the travelling direction. Thus, the metal particles without the orientation hit the surface of the base material 7 from the plural directions.

According to the aforementioned embodiment, three methods are introduced hereunder to have the metal particles sputtered from the target 5 hit the surface of the base material 7 from the plural directions. First, the base material 7 rotates relative to the target 5 in the deposition process. Second, the plural targets 5a, 5b are placed at the different positions to release the metal particles from each of the targets 5a, 5b. Third, the deposition pressure level is set equal to or higher than 0.7 Pa.

Further, the deposition rate is favorably equal to or higher than 6.0 nanometers per second, or 6.0 nm/sec. in the deposition process. In a case where the deposition process is operated by sputtering, the deposited film receives energy when the energized metal particles M are deposited on the base material 7. The film further receives energy generated by radiant ray from the target 5. The energy becomes greater as the deposition speed is higher. Thus, in a case where the deposition rate is sufficiently high (for example, equal to or higher than 6.0 nm/sec.), the temperature of the metal thin film tends to be high because the great amount of energy is stored in the metal thin film in the deposition process. Then, when the temperature of the metal thin film is lowered to normal temperature after the deposition, the metal thin film shrinks to include higher level of internal tensile stress. Thus, the metal thin film is formed with the cracks without heating the metal thin film by heating method after the deposition process.

The target 5 may be made of any metals, however, favorably be made of Chrome (Cr), Nickel (Ni), or stainless steel. In a case where the film is formed on the surface of the base material 7 using these metals, the film may include metallic luster and the net-shaped cracks whose size does not impair the designability of the door handle.

In the deposition process, the thickness of the metal thin film which is formed on the surface of the base material 7 is favorably equal to or higher than 10 nanometers, or 10 nm and equal to or lower than 200 nm. In a case where the thickness of the film is within the aforementioned range, which is equal to or higher than 10 nm and equal to or lower than 200 nm, the net-shaped cracks may be formed in a favorable size in the crack forming process. Accordingly, the metal film may be formed with high radio wave permeability and high electrical insulation properties while having the favorable designability of the exterior appearance of the door handle.

Further, the deposition process may be operated by the aforementioned sputtering or by a vapor deposition. In the sputtering, the metal particles are released from the target. In the vapor deposition method, a vaporized metal (metal vapor) is released from the target.

A first practical example will be explained. The surface of the base material 7 is formed with a smooth layer which is made of acryl resin, and is deposited with a chrome thin film using a bulk metal (a solid metal) of chrome as the target 5 in the deposition process. The sputtering device 1 shown in FIG. 1 is used under the deposition condition as follows. The deposition rate corresponds to 3.0 nm/sec. (with the power of 5 kilowatts, or 5 kw). The thickness of the film corresponds to 30 nm. The deposition pressure level corresponds to 0.3 Pa. Argon flow rate corresponds to 35 standard cubic centimeters per minute, or 35 sccm.

According to the first practical example, in the deposition processing, the base material 7 rotates relative to the target 5 to have chrome particles sputtered from the target 5 hit the surface of the base material 7 from the plural directions. In this case, the table 4 on which the base material 7 is mounted rotates at the rotation speed of 120 rotations per minute, or 120 rpm. After the deposition process, the base material 7 is held in the thermostatic oven at the atmospheric temperature of 80° C. for 30 minutes to be heated. Accordingly, thermal stress is generated by a difference between a coefficient of linear thermal expansion of the base material 7 and a coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A second practical example will be explained. The surface of the base material 7 is formed with the smooth layer which is made of acryl resin, and is deposited with the chrome thin film using a bulk metal (solid metal) of chrome as the target 5 in the deposition process. The sputtering device 1 shown in FIG. 1 is used under the deposition condition as follows. The deposition rate corresponds to 6.0 nm/sec. (with the power of 10 kw). The thickness of the film corresponds to 30 nm. The deposition pressure level corresponds to 0.3 Pa. Argon flow rate corresponds to 35 sccm.

According to the second practical example, in the deposition processing, the base material 7 rotates relative to the target 5 to have chrome particles sputtered from the target 5 hit the surface of the base material 7 from the plural directions. In this case, the table 4 on which the base material 7 is mounted rotates at the rotation speed of 120 rpm. The cracks are formed by internal tensile stress of the film, the internal tensile stress generated in the deposition process, without operating the heating process in the crack forming process. As above, the metal film is formed on the surface of the non-electric conductive base material 7 via the deposition process and the crack forming process.

A third practical example will be explained. The surface of the base material 7 is formed with the smooth layer which is made of acryl resin, and is deposited with the chrome thin film using a bulk metal (solid metal) of chrome as the target 5 in the deposition process. The sputtering device 1 shown in FIG. 1 is used under the deposition condition as follows. The deposition rate corresponds to 3.0 nm/sec. (with the power of 5 kw). The thickness of the film corresponds to 30 nm. The deposition pressure level corresponds to 2.0 Pa. Argon flow rate corresponds to 200 sccm.

According to the third practical example, the table 4 is at a standstill in the deposition process. Thus, the orientation, or the posture of the base material 7 relative to the target 5 does not change in the deposition process. After the deposition process, the base material 7 is held in the thermostatic oven at the atmospheric temperature of 80° C. for 30 minutes to be heated. Accordingly, thermal stress is generated by the difference between the coefficient of linear thermal expansion of the base material 7 and the coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A fourth practical example will be explained. The surface of the base material 7 is formed with the smooth layer which is made of acryl resin, and is deposited with the chrome thin film using a bulk metal (solid metal) of chrome as the target 5 in the deposition process. In this case, as shown in FIG. 6, the two targets 5a, 5b are placed at the different positions, and are used simultaneously to have the chrome particles sputtered from the two targets 5a, 5b hit the base material 7. The sputtering device 1 shown in FIG. 1 is used under the deposition condition as follows. The deposition rate corresponds to 0.6 nm/sec. (with the power of 0.3 kw per target 5a, 5b). The thickness of the film corresponds to 30 nm. The deposition pressure level corresponds to 0.5 Pa. Argon flow rate corresponds to 20 sccm.

According to the fourth practical example, the table 4 is at a standstill in the deposition process. Thus, the orientation, or the posture of the base material 7 relative to the target 5 does not change in the deposition process. After the deposition process, the base material 7 is held in the thermostatic oven at the atmospheric temperature of 80° C. for 30 minutes to be heated. Accordingly, thermal stress is generated by the difference between the coefficient of linear thermal expansion of the base material 7 and the coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A fifth practical example will be explained. The surface of the base material 7 is formed with the smooth layer which is made of acryl resin, and is deposited with the chrome thin film using a bulk metal (solid metal) of chrome as the target 5 in the deposition process. In this case, as shown in FIG. 6, the two targets 5a, 5b are placed at different positions, and are used alternately to have the chrome particles sputtered from the two targets 5a, 5b hit the base material 7. The sputtering device 1 shown in FIG. 1 is used under the deposition condition as follows. The deposition rate corresponds to 0.3 nm/sec. (with the power of 0.3 kw). The thickness of the film corresponds to 30 nm. The deposition pressure level corresponds to 0.5 Pa. Argon flow rate corresponds to 20 sccm.

According to the fifth practical example, the table 4 is at a standstill in the deposition process. Thus, the orientation, or the posture of the base material 7 relative to the target 5 does not change in the deposition process. After the deposition process, the base material 7 is held in the thermostatic oven at the atmospheric temperature of 80° C. for 30 minutes to be heated. Accordingly, thermal stress is generated by the difference between the coefficient of linear thermal expansion of the base material 7 and the coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A sixth practical example will be explained. The surface of the base material 7 is formed with the smooth layer which is made of acryl resin, and is deposited with the chrome thin film using a bulk metal (solid metal) of chrome as the target 5 in the deposition process. The sputtering device 1 shown in FIG. 1 is used under the deposition condition as follows. The deposition rate corresponds to 3.0 nm/sec. (with the power of 5 kw). The thickness of the film corresponds to 30 nm. The deposition pressure level corresponds to 0.7 Pa. Argon flow rate corresponds to 70 sccm.

According to the sixth practical example, the table 4 is at a standstill in the deposition process. Thus, the orientation, or the posture of the base material 7 relative to the target 5 does not change in the deposition process. After the deposition process, the base material 7 is held in the thermostatic oven at the atmospheric temperature of 80° C. for 30 minutes to be heated. Accordingly, thermal stress is generated by the difference between the coefficient of linear thermal expansion of the base material 7 and the coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A seventh practical example will be explained. The surface of the base material 7 is formed with the smooth layer which is made of acryl resin, and is deposited with the chrome thin film using a bulk metal (solid metal) of chrome as the target 5 in the deposition process. The sputtering device 1 shown in FIG. 1 is used under the deposition condition as follows. The deposition rate corresponds to 3.0 nm/sec. (with the power of 5 kw). The thickness of the film corresponds to 30 nm. The deposition pressure level corresponds to 1.0 Pa. Argon flow rate corresponds to 100 sccm.

According to the seventh practical example, the table 4 is at a standstill in the deposition process. Thus, the orientation, or the posture of the base material 7 relative to the target 5 does not change in the deposition process. After the deposition process, the base material 7 is held in the thermostatic oven at the atmospheric temperature of 80° C. for thirty minutes to be heated. Accordingly, thermal stress is generated by the difference between the coefficient of linear thermal expansion of the base material 7 and the coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A first comparison example will be explained. The surface of the base material 7 is formed with the smooth layer which is made of acryl resin, and is deposited with the chrome thin film using a bulk metal (solid metal) of chrome as the target 5 in the deposition process. The sputtering device 1 shown in FIG. 1 is used under the deposition condition as follows. The deposition rate corresponds to 3.0 nm/sec. (with the power of 5 kw). The thickness of the film corresponds to 30 nm. The deposition pressure level corresponds to 0.3 Pa. Argon flow rate corresponds to 35 sccm.

According to the first comparison example, the table 4 is at a standstill in the deposition process. Thus, the orientation, or the posture of the base material 7 relative to the target 5 does not change in the deposition process. After the deposition process, the base material 7 is held in the thermostatic oven at the atmospheric temperature of 80° C. for 30 minutes to be heated. Accordingly, thermal stress is generated by the difference between the coefficient of linear thermal expansion of the base material 7 and the coefficient of linear thermal expansion of chrome thin film. Thermal stress is applied to the chrome thin film to form cracks in the chrome thin film in the crack forming process. Thus, the metal film is formed on the surface of the non-electric conductive base material 7 via the deposition process and the crack forming process.

A second comparison example will be explained. Six plate-shaped test panels made of synthetic resin of PC resin and PBT resin as a base material are formed. Each surface of the six test panels includes the smooth layer which is made of, for example, acryl resin with a thickness of 20 micrometers, or 20 μm. The six test panels which are formed with the smooth layers, respectively, are mounted on predetermined positions on the table 4 of the sputtering device 1 shown in FIG. 1.

According to the second comparison example, the chrome thin film is deposited on each surface of the test panel using a bulk metal (solid metal) of chrome as the target 5. The sputtering device 1 shown in FIG. 1 is used under the deposition condition as follows. The deposition rate corresponds to 3.0 nm/sec. (with the power of 5 kw). The thickness of the film corresponds to 30 nm. The deposition pressure level corresponds to 0.3 Pa. Argon flow rate corresponds to 35 sccm.

According to the second comparison example, the table 4 is at a standstill in the deposition process. Thus, the orientation, or the posture of each of the test panels relative to the target 5 does not change in the deposition process. After the deposition process, the test panels are held in the thermostatic oven and are held at the atmospheric temperature of 80° C. for 30 minutes to be heated. Accordingly, thermal stress is generated by the difference between the coefficient of linear thermal expansion of the test panels and the coefficient of linear thermal expansion of chrome thin film. Thermal stress is applied to the chrome thin film to form cracks in the chrome thin film. Thus, the metal film is formed on each of the surfaces of the test panels via the deposition process and the crack forming process.

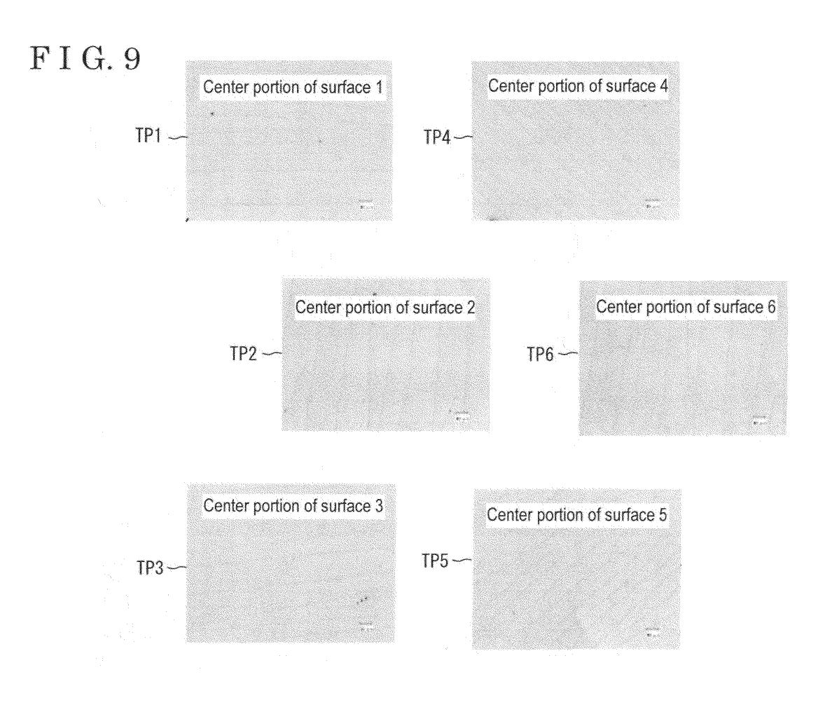

As shown in FIGS. 9, TP1 and TP3 are formed with the lined cracks extending in an up-down direction. TP2 and TP6 are formed with the lined cracks extending in a transverse direction. TP4 and TP 5 are formed with the lined cracks extending in an oblique direction. The lined crack extends in a direction which relates to the positions of the test panel on the table 4 and the target 5. In particular, the lined crack is formed on each metal surface of the test panel along a direction orthogonal to each segment defined between a center of the target 5 and each center of the test panels. These cracks not only impair the exterior appearance of the door handle but also deteriorating the electrical insulation properties along the extending direction of the lined cracks, that is, in the positions where the lined cracks are formed.

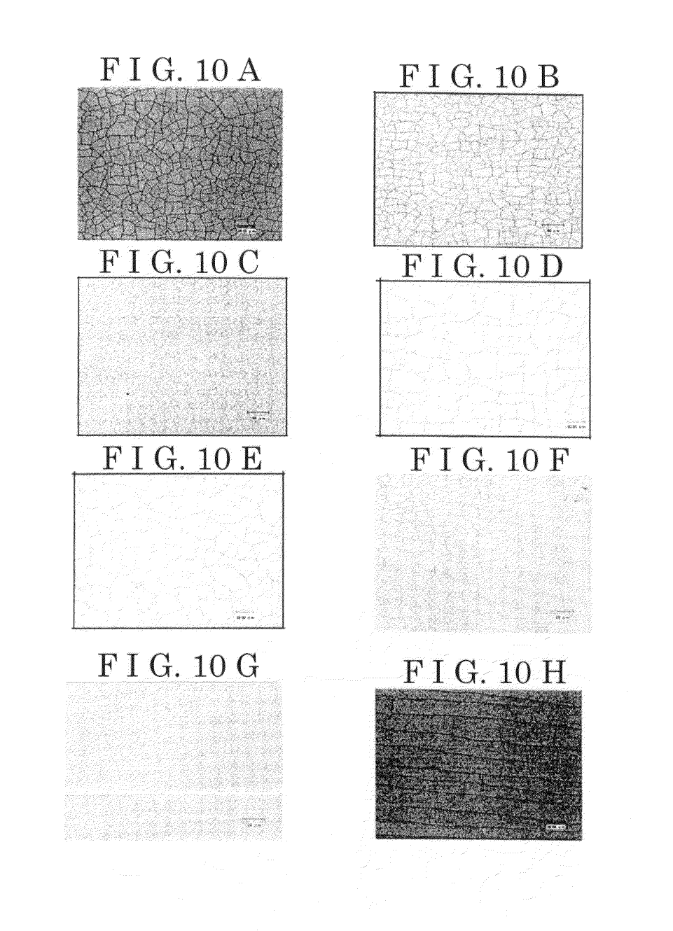

As shown in FIG. 10A to FIG. 10H, the metal films according to the first practical example to the seventh practical example are formed with the net-shaped cracks, whereas the metal film according to the first comparison example is formed with the lined cracks.

In a following Table 1, the deposition condition of the metal film, the heating process after the deposition, the rotation of the base material, the door handle exterior appearance evaluation result, the measured value of electrical surface resistance, the evaluation result of the antenna and the evaluation result of the touch sensor according to the first to the seventh practical examples and the first comparison example are shown.

TABLE 1

| | | First | Second | Third | Fourth | Fifth | Sixth | Seventh | First |
|---|---|---|---|---|---|---|---|---|---|
| | | practical | practical | practical | practical | practical | practical | practical | comparison |
| | | example | example | example | example | example | example | example | example |
| Deposition rate | | 3.0 | 6.0 | 3.0 | 0.6 | 0.3 | 3.0 | 3.0 | 3.0 |
| [nm/sec.] | | | | | | | | | |
| Film thickness [nm] | | 30 | 30 | 30 | 30 | 30 | 30 | 30 | 30 |
| Deposition pressure | | 0.3 | 0.3 | 2.0 | 0.5 | 0.5 | 0.7 | 1.0 | 0.3 |
| level [Pa] | | | | | | | | | |
| Argon flow rate [sccm] | | 35 | 35 | 200 | 20 | 20 | 70 | 100 | 35 |
| Arrangement of target | | 1 | 1 | 1 | 2 | 2 | 1 | 1 | 1 |
| Heating process | | Yes | No | Yes | Yes | Yes | Yes | Yes | Yes |
| Rotation of base | | Yes | Yes | No | No | No | No | No | No |
| material | | | | | | | | | |
| Evaluation of exterior | | Satisfied | Satisfied | Satisfied | Satisfied | Satisfied | Satisfied | Satisfied | Not satisfied |
| appearance | | | | | | | | | |
| Electrical | Before | 5.7 × 10² | 3.3 × 10⁵ | 2.5 × 10² | 1.4 × 10² | 9.3 × 10¹ | 7.1 × 10² | 4.6 × 10² | 1.2 × 10¹ |
| surface | After | 5.2 × 10⁸ | | 1.9 × 10⁷ | 4.6 × 10⁶ | 1.8 × 10⁶ | 2.3 × 10⁷ | 1.1 × 10⁷ | 3.5 × 10² |
| resistance | | | | | | | | | |
| before/aft | | | | | | | | | |
| er heating | | | | | | | | | |
| [Ω/□] | | | | | | | | | |

| | | | | | | | | |
|---|---|---|---|---|---|---|---|---|
| Evaluation of antenna | Satisfied | Satisfied | Satisfied | Satisfied | Satisfied | Satisfied | Satisfied | Satisfied |
| Evaluation of touch | Satisfied | Satisfied | Satisfied | Satisfied | Satisfied | Satisfied | Satisfied | Not satisfied |
| sensor | | | | | | | | |

According to the Table 1, the arrangement of the target shows the number of the target used in the deposition processing. In a case where the arrangement of the target shows as 1, one target is used for deposition. In a case where the arrangement of target shows as 2, two targets are placed at different positions to be used for deposition. According to the evaluation of the exterior appearance of the door handle, in a case where the lined cracks are not observed on the surface of the metal film by visual inspection, the evaluation shows as Satisfied. In a case where the lined cracks are observed on the surface of the metal film by visual inspection, the evaluation shows as Not satisfied. The evaluation of the antenna is based on whether the door handle for the smart entry system, being formed using the base material 7 on which the metal film is formed by each of the practical examples and the first comparison example, receives signals from the smart key precisely. In a case where the door handle for the smart entry system receives the signals precisely, the evaluation shows as Satisfied. In a case where the door handle for the smart entry system does not receive the signals precisely, the evaluation shows as Not satisfied. The evaluation of the touch sensor is based on whether the door handle for the smart entry system, being formed using the base material 7 on which the metal film is formed by each of the practical examples and the first comparison example, operates an incorrect operation by opening/closing the door of the vehicle in a case where the position other than the predetermined position of the door handle for the smart entry system is touched. In a case where the incorrect operation is not operated, the evaluation shows as Satisfied. In a case where the incorrect operation is operated, the evaluation shows as Not satisfied. The electrical surface resistance is measured by a four-terminal method. In a case where the electrical surface resistance is equal to or higher than 10⁸ ohms per square, or 10⁸ Ω/sq., Hiresta UPMCP-HT450 of Mitsubishi Chemical Analytech Co., Ltd. is used. In a case where the electrical surface resistance is lower than 10⁸ Ω/sq., Loresta GPMCP-T600 of Mitsubishi Chemical Analytech Co., Ltd. is used.

As shown in Table 1, each of the first practical example to the seventh practical example shows as Satisfied in the evaluation of the exterior appearance of the door handle, the evaluation of the antenna, and the evaluation of the touch sensor. The metal films according to the first, third, fourth, fifth, sixth and seventh practical examples include high surface resistance after the heating process. Thus, the metal films according to the first, third, fourth, fifth, sixth and seventh practical examples include high electrical insulation properties. The metal film according to the second practical example includes higher surface resistance even though the heating process after the deposition is not operated. Thus, the metal film according to the second practical example includes high electrical insulation properties. On the other hand, according to the first comparison example, the evaluation of the exterior appearance of the door handle and the evaluation of the touch sensor show as Not satisfied. Accordingly, the metal film according to the embodiment includes high radio wave permeability and high electrical insulation properties while having the favorable designability of the exterior appearance of the door handle. Thus, the metal film according to the embodiment is assumed to be greatly useful.

As above, the method for manufacturing the metal film according to the embodiment includes the deposition process and the crack forming process. In the deposition process, the metal particles are released from the target 5 which is made of solid metal by sputtering, and hit the surface of the non-electric conductive base material 7 from the plural directions to deposit the metal film on the surface of the base material 7. In the crack forming process, thermal stress is applied to the metal thin film to form the cracks in the metal thin film.

According to the embodiment, because the metal particles are released from the target 5 which is made of solid metal and hit the surface of the non-electric conductive base material 7 from the plural directions in the deposition process, the metal particles forms the metal thin film by depositing on the surface of the base material 7 without directing in a specific direction. Thus, in a case where thermal stress is applied to the metal thin film which is formed with the metal particles which deposit on the surface of the base material 7 without directing in a specific direction, the surface of the metal thin film cracks to form the cracks of similar sizes without the orientation. Accordingly, the net-shaped cracks of similar sizes are formed. That is, the metal thin film is divided into minute island-shaped blocks by having the net-shaped cracks. The cracks extending in a specific direction are not formed. Because the cracks are not observed as lines on the metal thin film, the metal thin film includes the high electrical insulation properties (high surface resistance) and the high radio wave permeability without impairing the designability of the exterior appearance of the door handle. According to the method for manufacturing the metal film of the embodiment, the metal thin film may be formed to include the high electrical insulation properties (high surface resistance) and the high radio wave permeability while having the favorable designability of the exterior appearance of the door handle.

According to the first and second practical examples, the chrome particles released from the target 5 hit the surface of the base material 7 from the plural directions by rotating the base material 7 relative to the target 5. Thus, the chrome thin film may be formed with the net-shaped cracks. Accordingly, the metal thin film may be formed to include the high electrical insulation properties and the high radio wave permeability while having the favorable designability of the exterior appearance of the door handle.

According to the fourth and fifth practical examples, the plural targets 5a, 5b are placed at the different positions and release the chrome particles so that the chrome particles hit the surface of the base material 7 from the plural directions. Because the chrome thin film may be formed with the net-shaped cracks, the metal thin film may be formed to include the high electrical insulation properties (high surface resistance) and the high radio wave permeability while having the favorable designability of the exterior appearance of the door handle. According to the fourth practical example, the two targets 5a, 5b are used simultaneously in the deposition process, whereas the two targets 5a, 5b are used alternately in the deposition process according to the fifth practical example. In both cases, the metal thin film may be formed to include the high electrical insulation properties and the high radio wave permeability while having the favorable designability of the exterior appearance of the door handle.

According to the third, sixth, and seventh practical examples, the frequency of the hitting of the chrome particles released from the target 5 to the molecules which are in the atmosphere increases by setting the deposition pressure level higher, for example, equal to or higher than 0.7 Pa. Because the chrome particles travel in a random direction, or in any direction, the chrome particles hit the surface of the base material 7 from the plural directions. Thus, the chrome thin film may be formed with the net-shaped cracks. Accordingly, the metal thin film may be formed to include the high electrical insulation properties and the high radio wave permeability while having the favorable designability of the exterior appearance of the door handle.

According to the first, third, fourth, fifth, sixth and seventh practical examples, the base material 7 on which the chrome thin film is formed is heated. Accordingly, thermal stress is generated on the chrome thin film by the difference between the coefficient of linear thermal expansion of the base material 7 and the coefficient of linear thermal expansion of chrome thin film. Thus, the chrome thin film may be formed to include the net-shaped cracks of similar sizes by thermal stress.

According to the second practical example, the deposition rate of the chrome thin film is set higher, which corresponds to 6.0 nm/sec. in the deposition process. Thus, the chrome thin film is sufficiently heated in the deposition process, whereas thermal stress greatly influences on the chrome thin film when the chrome thin film is cooled after the deposition process. Accordingly, the net-shaped cracks of similar sizes are formed on the chrome thin film. That is, because thermal stress influences on the chrome thin film using the heat generated in the deposition process, the metal thin film may be formed with the net-shaped cracks without heating the chrome thin film after the deposition process.

The disclosure is explained with the embodiment, however, is not limited to the aforementioned embodiment. For example, according to the aforementioned embodiment, the deposition process is operated by sputtering, however, may be operated using the vapor deposition. According to the embodiment, the base material 7 corresponds to the door handle body of the door handle for the smart entry system. Alternatively, the disclosure may be applied to any materials as long as the materials are required to include high radio wave permeability and high electrical insulation properties while having metallic luster.

According to the aforementioned embodiment, the method for manufacturing the metal film being formed on the surface of a non-electric conductive base material 7 includes processes of the deposition process of releasing a metal M, M1, M2 being formed in a particle or being vaporized from at least one of targets 5, 5a, 5b, the target 5, 5a, 5b being made of solid metal, and depositing the metal thin film on the surface of the base material 7 by having the released metal M, M1, M2 hit the surface of the base material 7 from a plurality of directions; and the crack forming process of forming the crack in the metal thin film by applying thermal stress to the metal thin film.

According to the aforementioned embodiment, the deposition process may be operated by the sputtering or the vapor deposition. According to the aforementioned disclosure, the plural directions are defined to include different deposition angles of the metal released from the target relative to the surface of the base material 7 when the metal particles hit the surface of the base material 7. In particular, the metal may be deposited to the surface of the base material 7 from the plural directions which favorably include at least two positions opposite to each other, or intersect each other from the opposite direction relative to the perpendicular line relative to the surface of the base material 7 when seeing from a direction parallel to the surface of the base material 7.

According to the aforementioned disclosure, in the deposition process, the metal formed in particles or being vaporized is released from the target 5 which is made of solid metal and hits the surface of the non-electric conductive base material 7 from the plural directions by the sputtering and the vaporized deposition. Accordingly, the metal fixed on the surface of the base material 7 is deposited on the surface of the base material 7 without directing in a specific direction. Accordingly, the metal thin film is formed. Thus, in a case where thermal stress is applied to the metal thin film, the surface of the metal thin film cracks to form the cracks of similar sizes without the orientation. Accordingly, the net-shaped cracks of similar sizes are formed. That is, the metal thin film is divided into the minute island-shaped blocks by the having net-shaped cracks. The cracks extending in a specific direction are not formed. Because the cracks are not observed as lines on the metal thin film, the metal thin film includes the high electrical insulation properties (high surface resistance) and the high radio wave permeability without impairing the designability of the exterior appearance of the door handle. According to the method for manufacturing the metal film of the embodiment, the metal thin film may be formed to include the high electrical insulation properties and the high radio wave permeability while having the favorable designability of the exterior appearance of the door handle.

According to the aforementioned disclosure, the metal released from the target 5 may be either formed in particles or vaporized. In the sputtering, metal released from the target 5 is formed in particles. In the vapor deposition, the surface of the target 5 is vaporized and releases the vaporized metal. Either in the sputtering or the vapor deposition, the metal immediately after being released from the target 5 travels in a specific direction. According to the disclosure, the metal particles including a specific orientation and released from the target 5 hit the surface of the base material 7 from the plural positions.

According to the aforementioned embodiment, the metal M, M1, M2 being released from the target 5, 5a, 5b hits the surface of the base material 7 from the plural directions by rotating the base material 7 relative to the target 5, 5a, 5b in the deposition process.

According to the aforementioned embodiment, the orientation, or the posture of the base material 7 relative to the metal changes continuously, the metal which is released from the target and travels in a specific direction. Thus, the metal hits the surface of the base material 7 from the plural directions.

According to the aforementioned embodiment, the metal M, M1, M2 being released from the plural targets 5, 5a, 5b hits the surface of the base material 7 from the plural directions by placing the plural targets 5, 5a, 5b at different positions and by releasing the metal M, M1, M2 from each of the plural targets 5, 5a, 5b in the deposition process.

According to the aforementioned embodiment, the frequency of the hitting of metal released from the target 5 to the molecules which are in the atmosphere increases as the pressure level in the deposition process (the deposition pressure level) increases. When the metal released from the target 5 hits the molecules in the atmosphere, the travelling direction of the metal changes continuously due to the collision with the molecules. Thus, the metal further loses the orientation in the travelling direction as the frequency of the hitting of metal to the molecules increases.

According to the aforementioned embodiment, the metal M, M1, M2 being released from the target 5, 5a, 5b hits the surface of the base material 7 from the plurality of directions by setting the pressure level when depositing the metal M, M1, M2 at equal to or higher than 0.7 Pascals in the deposition process.

According to the aforementioned embodiment, in a case where the deposition pressure level is equal to or higher than 0.7 Pa, the metal released from the target 5 hits the surface of the base material 7 from the plural directions after losing the orientation by hitting the molecules in the atmosphere repeatedly. That is, according to the disclosure, the metal released from the target 5 hits the surface of the base material 7 from the plural direction by simply setting the pressure level in the deposition process equal to or higher than 0.7 Pa.

According to the aforementioned embodiment, the metal thin film is generated with the cracks in the crack forming process by heating the base material 7 including the surface on which the metal thin film is formed during the deposition process.

According to the aforementioned embodiment, thermal stress is generated by a difference between the coefficient of linear thermal expansion of the base material 7 and the coefficient of linear thermal expansion of the metal thin film by heating the base material 7 and the metal thin film which is deposited on the surface of the base material 7. Then, thermal stress may be applied to the metal thin film. By applying thermal stress to the metal thin film, the metal thin film is formed to include the net-shaped cracks of similar sizes. The heating temperature may favorably be equal to or higher than 60° C., and may more favorably be equal to or higher than 80° C.

According to the aforementioned embodiment, the deposition rate of the metal thin film is set at equal to or higher than 6.0 nanometers per second in the deposition process.

In a case where the metal thin film is deposited by sputtering, argon gas which is in the atmosphere is plasmatized and heated. The heated argon ion hits the target 5 to sputter the metal particles M which are extremely heated. Thus, the greater amount of heat is stored in the film which is formed on the surface of the base material 7 as the deposition rate increases. In a case where the deposition rate is equal to or higher than 6.0 nm/sec., thermal stress greatly influences on the film when the metal thin film is cooled to the normal temperature after the deposition process. Accordingly, the net-shaped cracks of similar sizes are formed on the metal thin film. That is, according to the disclosure, because thermal stress influences on the metal thin film using the heat generated in the deposition process, the metal thin film may be formed with the net-shaped cracks without heating the metal thin film after the deposition process.

According to the aforementioned embodiment, the deposition process is operated by sputtering or vapor deposition.

According to the aforementioned embodiment, in the deposition process, the metal formed in particles or being vaporized is released from the target 5 which is made of solid metal and hits the surface of the non-electric conductive base material 7 from the plural directions by the sputtering and the vaporized deposition.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. A method for manufacturing a metal film being formed on a surface of a non-electric conductive base material, comprising processes of:
a deposition process of:
releasing a metal being formed in a particle or being vaporized from at least one of targets, the target being made of solid metal; and
depositing a metal thin film on the surface of the base material by having the released metal hit the surface of the base material from a plurality of directions; and
a crack forming process of:
forming a crack in the metal thin film by applying thermal stress to the metal thin film.

2. The method for manufacturing the metal film according to claim 1, wherein the metal being released from the target hits the surface of the base material from the plurality of directions by rotating the base material relative to the target in the deposition process.

3. The method for manufacturing the metal film according to claim 1, wherein the metal being released from the plurality of targets hits the surface of the base material from the plurality of directions by placing the plurality of targets at different positions and by releasing the metal from each of the plurality of targets in the deposition process.

4. The method for manufacturing the metal film according to claim 1, wherein the metal being released from the target hits the surface of the base material from the plurality of directions by setting a pressure level when depositing the metal at equal to or higher than 0.7 Pascals in the deposition process.

5. The method for manufacturing the metal film according to claim 1, wherein the metal thin film is generated with the cracks in the crack forming process by heating the base material including the surface on which the metal thin film is formed during the deposition process.

6. The method for manufacturing the metal film according to claim 1, wherein a deposition rate of the metal thin film is set at equal to or higher than 6.0 nanometers per second in the deposition process.

7. The method for manufacturing the metal film according to claim 1, wherein the deposition process is operated by sputtering or vapor deposition.
